(19) United States
(12) Patent Application Publication
(10) Pub. No.: US 2022/0310614 A1
(43) Pub. Date: Sep. 29, 2022

(54) Semiconductor Structure and Method for Manufacturing Semiconductor Structure

(71) Applicant: CHANGXIN MEMORY TECHNOLOGIES, INC., Hefei City (CN)

(72) Inventors: Kangshu ZHAN, Hefei (CN); JUN XIA, Hefei (CN); Qiang WAN, Hefei (CN); Tao LIU, Hefei (CN); Sen LI, Hefei (CN)

(73) Assignee: CHANGXIN MEMORY TECHNOLOGIES, INC., Hefei City (CN)

(21) Appl. No.: 17/574,913

(22) Filed: Jan. 13, 2022

Related U.S. Application Data
(63) Continuation of application No. PCT/CN2021/112136, filed on Aug. 11, 2021.

(30) Foreign Application Priority Data
Mar. 26, 2021 (CN) 202110328331.8

(51) Int. Cl. H01L 27/108; G11C 5/10

(52) U.S. Cl. CPC H01L 27/10805; G11C 5/10; H01L 27/1085

(57) ABSTRACT

The embodiments of the present disclosure belong to the technical field of semiconductor manufacturing, and relate to a semiconductor structure and a method for manufacturing a semiconductor structure. Each of a plurality of storage structures in the semiconductor structure includes a plurality of capacitor structures stacked in a direction perpendicular to a substrate, each of the plurality of capacitor structures includes a bottom plate and an top plate which are arranged opposite to each other, and a first dielectric layer located between the bottom plate and the top plate, and the bottom plate and the top plate are both parallel to the substrate, all bottom plates in each of the plurality of storage structures are electrically connected, and all top plates in each of the plurality of storage structures are electrically connected; the bottom plate and the top plate extend in a plane parallel to the substrate.

### CROSS-REFERENCE TO RELATED APPLICATIONS

The present disclosure is a continuation of International Patent Application No. PCT/CN2021/112136 filed on Aug. 11, 2021, which claims the priority of Chinese Patent Application No. 202110328331.8 filed on Mar. 26, 2021. The disclosures of the aforementioned patent applications are incorporated herein by reference in their entirety.

### TECHNICAL FIELD

The embodiments of the present disclosure relate to the technical field of semiconductor manufacturing, and in particular, to a semiconductor structure and a method for manufacturing a semiconductor structure.

### BACKGROUND

With gradual development of storage device technology, a dynamic random access memory (DRAM) is gradually applied in various electronic devices due to high density and fast read and write speed thereof. The dynamic random access memory generally includes a capacitor structure and a transistor structure; the transistor structure is connected to the capacitor structure, such that through the transistor structure, data stored in the capacitor structure is read or data is written into the capacitor structure.

With the gradual miniaturization of the dynamic random access memory, a thickness of the dynamic random access memory gradually decreases, and a central line of a tubular capacitor structure is provided perpendicular to a substrate, so that a height of the tubular capacitor structure decreases and a capacitance value decreases, causing insufficient charge storage capability of the capacitor structure.

### SUMMARY

The embodiments of the present disclosure provide a semiconductor structure, including:

a substrate; and

a plurality of storage structures provided on the substrate and distributed at intervals; and each of the plurality of storage structures includes a plurality of capacitor structures stacked in a direction perpendicular to the substrate, each of the plurality of capacitor structures includes a bottom plate and a top plate arranged opposite to each other, and a first dielectric layer located between the bottom plate and the top plate, and the bottom plate and the top plate are both parallel to the substrate; and

all bottom plates in each of the plurality of storage structures are electrically connected to one another, and all top plates in each of the plurality of storage structures are electrically connected to one another.

The embodiments of the present disclosure further provide a method for manufacturing a semiconductor structure, including:

manufacturing a substrate;

forming a plurality of repeated film layers stacked on the substrate, and each of the plurality of repeated film layers includes a first conductive layer, a first dielectric material layer, a second conductive layer and a second dielectric material layer which are stacked in sequence;

etching the plurality of repeated film layers in a direction perpendicular to the substrate, so as to form a plurality of storage structures arranged at intervals on the substrate;

forming second insulating blocks on side walls of the second conductive layer located between the first dielectric material layer and the second dielectric material layer;

forming a conductive film on each of the plurality of storage structures, and the conductive film is wrapped on outer side of each of the plurality of storage structures, and the conductive film is bonded to all first conductive layers in each of the plurality of storage structures;

removing a part of the conductive film, to form a connection port extending to the substrate on the conductive film;

forming an insulating film covering the conductive film;

forming a first insulating block on the first conductive layer corresponding to the connection port; and

removing the second insulating blocks corresponding to the connection port, and filling a conductive filler between adjacent storage structures, the conductive filler being bonded to the second conductive layer corresponding to the connection port.

### BRIEF DESCRIPTION OF THE DRAWINGS

In order to describe the technical solutions in the embodiments of the present disclosure or in the prior art more clearly, hereinafter, accompanying drawings requiring to be used for describing the embodiments or the prior art are introduced briefly. Apparently, the accompanying drawings in the following description merely relate to some embodiments of the present disclosure, and for a person of ordinary skill in the art, other accompanying drawings can also be obtained according to these accompanying drawings without involving any inventive effort.

FIG. 1 is a first schematic structural diagram of a semiconductor structure provided in the embodiments of the present disclosure;

FIG. 2 is a second schematic structural diagram of a semiconductor structure provided in the embodiments of the present disclosure;

FIG. 3 is a flowchart of a method for manufacturing a semiconductor structure provided in the embodiments of the present disclosure;

FIG. 4 is a schematic diagram after a plurality of repeated film layers are formed in the method for manufacturing the semiconductor structure provided in the embodiments of the present disclosure;

FIG. 5 is a schematic diagram after an etching pattern layer is formed in the method for manufacturing the semiconductor structure provided in the embodiments of the present disclosure;

FIG. 6 is a schematic diagram after storage structures are formed in the method for manufacturing the semiconductor structure provided in the embodiments of the present disclosure;

FIG. 7 is a top view of FIG. 6;

FIG. 8 is a schematic diagram after second insulating blocks and intermediate insulating blocks are formed in the method for manufacturing the semiconductor structure provided in the embodiments of the present disclosure;

FIG. 9 is a schematic diagram after the intermediate insulating blocks are removed in the method for manufacturing the semiconductor structure provided in the embodiments of the present disclosure;

FIG. 10 is a schematic diagram after conductive films are formed in the method for manufacturing the semiconductor structure provided in the embodiments of the present disclosure;

FIG. 11 is a top view of FIG. 10;

FIG. 12 is a schematic diagram after a mask layer is formed in the method for manufacturing the semiconductor structure provided in the embodiments of the present invention;

FIG. 13 is a top view of FIG. 12;

FIG. 14 is a schematic diagram after connection ports are formed in the method for manufacturing the semiconductor structure provided in the embodiments of the present disclosure;

FIG. 15 is a top view of FIG. 14;

FIG. 16 is a schematic diagram after insulating films and first insulating blocks are formed in the method for manufacturing the semiconductor structure provided in the embodiments of the present disclosure;

FIG. 17 is a top view of FIG. 16;

FIG. 18 is a schematic diagram after some of the second insulating blocks are removed in the method for manufacturing the semiconductor structure provided in the embodiments of the present disclosure;

FIG. 19 is a top view of FIG. 18;

FIG. 20 is a schematic diagram after a conductive filler is formed in the method for manufacturing the semiconductor structure provided in the embodiments of the present disclosure; and

FIG. 21 is a top view of FIG. 20.

### DESCRIPTION OF REFERENCE SIGNS

10: storage structure;
101: conductive film;
102: insulating film;
103: intermediate insulating block;
104: connection port;
20: substrate;
201: contact pad;
30: capacitor structure;
301: bottom plate;
302: top plate;
303: first dielectric layer;
304: second dielectric layer;
305: first insulating block;
306: second insulating block;
40: conductive filler;
50: repeated film layer;
501: first conductive layer;
502: second conductive layer;
503: first dielectric material layer;
504: second dielectric material layer;
60: etching pattern layer;
70: mask layer.

### DETAILED DESCRIPTION OF THE EMBODIMENTS

In order to make objects, technical solutions and advantages of some embodiments of the present disclosure clearer, hereinafter, the technical solutions in the embodiments of the present disclosure will be described clearly and completely with reference to the accompanying drawings of the embodiments of the present disclosure. Obviously, the embodiments as described are only some of the embodiments of the present disclosure, and are not all of the embodiments. All other embodiments obtained by a person of ordinary skill in the art on the basis of the embodiments of the present disclosure without any inventive effort shall all fall within the scope of protection of some embodiments of the present disclosure.

A dynamic random access memory (DRAM) includes a capacitor structure and a transistor structure, and a gate electrode of the transistor structure is connected to a word line, a drain electrode of the transistor structure is connected to a bit line, and a source electrode of the transistor structure is connected to the capacitor structure; a voltage signal on the word line can control the turn on or off of the transistor, so as to read, through the bit line, data stored in the capacitor structure, or write, through the bit line, data into the capacitor structure.

The embodiments of the present disclosure provide a semiconductor structure. A plurality of capacitor structures are stacked on a substrate in a direction perpendicular to the substrate, each of the plurality of capacitor structures includes a bottom plate and a top plate arranged opposite to each other, the bottom plate and the top plate are both arranged parallel to the substrate, and a first dielectric layer is located between the bottom plate and the top plate; the bottom plate and the top plate constitute the capacitor structure extend in a plane parallel to the substrate, and when a thickness of the semiconductor structure decreases, areas of the bottom plate and the top plate will not be decreased. Compared with a tubular capacitor structure, a capacitance value of the plurality of capacitor structures is improved, thereby improving the charge storage capability of the semiconductor structure.

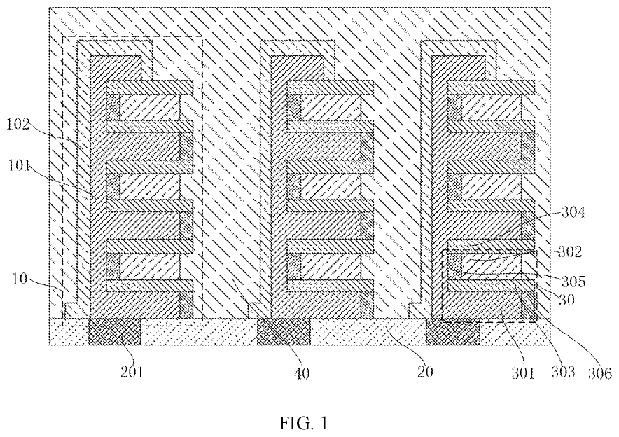

Please refer to FIG. 1, the semiconductor structure provided in this embodiment includes a substrate 20, and the substrate 20 can be in a plate shape, so that the substrate 20 can serve as a foundation of other subsequent structures. Exemplarily, materials forming the substrate 20 can include insulation materials such as silicon nitride and silicon oxide, and the materials of the substrate 20 is not limited in this embodiment.

Further, the semiconductor structure further includes a plurality of storage structures 10 arranged on the substrate 20, and each of the plurality of storage structures 10 forms a capacitor for storing data. In particular, the plurality of storage structures 10 are provided at intervals on the substrate 20; that is to say, the plurality of storage structures 10 are arranged at intervals in a plane parallel to the substrate 20. Exemplarily, the plurality of storage structures 10 can be arranged in an array on the substrate 20.

In the described implementation, each of the plurality of storage structures 10 includes a plurality of capacitor structures 30, and the plurality of capacitor structures 30 are stacked in a direction perpendicular to the substrate 20. Exemplarily, projections of all capacitor structures 30 of each of the plurality of storage structures 10 on the substrate 20 can completely coincide.

Continue to refer to FIG. 1, specifically, each of the plurality of capacitor structures 30 includes a bottom plate 301 and an top plate 302 arranged opposite to each other, and a first dielectric layer 303 is located between the bottom plate 301 and the top plate 302, and the bottom plate 301, the top plate 302 and the first dielectric layer 303 are all provided parallel to the substrate 20; and the bottom plate 301 serves as one polar plate of a capacitor, the top plate 302 serves as another polar plate of the capacitor, and the first dielectric layer 303 serves as a dielectric of the capacitor. It should be noted that the bottom plate 301 of each of the plurality of capacitor structures 30 can be arranged close to the substrate 20, or the top plate 302 of each of the plurality of capacitor structures 30 can be arranged close to the substrate 20, which is not limited in this embodiment.

In this embodiment, both the bottom plate 301 and the top plate 302 are made of conductive materials. Exemplarily, a material of the bottom plate 301 can include polysilicon etc., and a material of the top plate 302 can include aluminum etc.; and a material of the first dielectric layer 303 can be a material with a relatively high dielectric constant (such as hafnium silicate oxide, hafnium oxide, and zirconium oxide).

In the described implementation, all bottom plates 301 of all capacitor structures 30 in each of the plurality of storage structures 10 are electrically connected to one another, and all top plates 302 of all capacitor structures 30 in each of the plurality of storage structures 10 are electrically connected to one another. That is to say, all capacitor structures 30 in each of the plurality of storage structures 10 are connected in parallel to form a capacitor for storing data.

In the semiconductor structure provided in the present embodiment, the plurality of storage structures 10 are arranged at intervals on the substrate 20, each of the plurality of storage structures 10 includes the plurality of capacitor structures 30 stacked in the direction perpendicular to the substrate 20; each of the plurality of capacitor structures 30 includes the bottom plate 301 and the top plate 302 arranged opposite to each other, and the first dielectric layer 303 is located between the bottom plate 301 and the top plate 302, the bottom plate 301 and the top plate 302 are both parallel to the substrate 20, all bottom plates 301 in each of the plurality of storage structures 10 are electrically connected, and all top plates 302 in each of the plurality of storage structures 10 are electrically connected. Both the bottom plate 301 and the top plate 302 are parallel to the substrate 20, and the bottom plate 301 and the top plate 302 extend in a plane parallel to the substrate 20, the a decrease in a height of the semiconductor structure does not affect areas of the bottom plate 301 and the top plate 302, and thus, compared with a tubular capacitor structure, a capacitance value of the plurality of capacitor structures is increased, further improving charge storage capability of the semiconductor structure.

Continue to refer to FIG. 1, in an implementation in which the bottom plate 301 of each of the plurality of capacitor structures 30 constituting the semiconductor structure is arranged close to the substrate 20, a second dielectric layer 304 is provided between adjacent capacitor structures 30. With such an arrangement, in the adjacent capacitor structures 30, the capacitor structure close to the substrate 20 is a first capacitor structure, the capacitor structure away from the substrate 20 is a second capacitor structure, the top plate 302 of the first capacitor structure, the bottom plate 301 of the second capacitor structure, and the second dielectric layer 304 also form a capacitor, and thus the capacitance value of the storage structure 10 can be further increased, so as to further improve the charge storage capability of the semiconductor structure.

Exemplarily, the material of the first dielectric layer 303 and a material of the second dielectric layer 304 can be same, so that a capacitance value of each of the plurality of capacitor structures 30 is equal to a capacitance value of a capacitor formed by the adjacent capacitor structures 30, that is to say, a capacitance value of a capacitor with the first dielectric layer 303 as a dielectric is equal to a capacitance value of a capacitor with the second dielectric layer 304 as a dielectric, so as to improve performance of the semiconductor structure. Certainly, in other implementations, the material of the first dielectric layer 303 and the material of the second dielectric layer 304 can also be different.

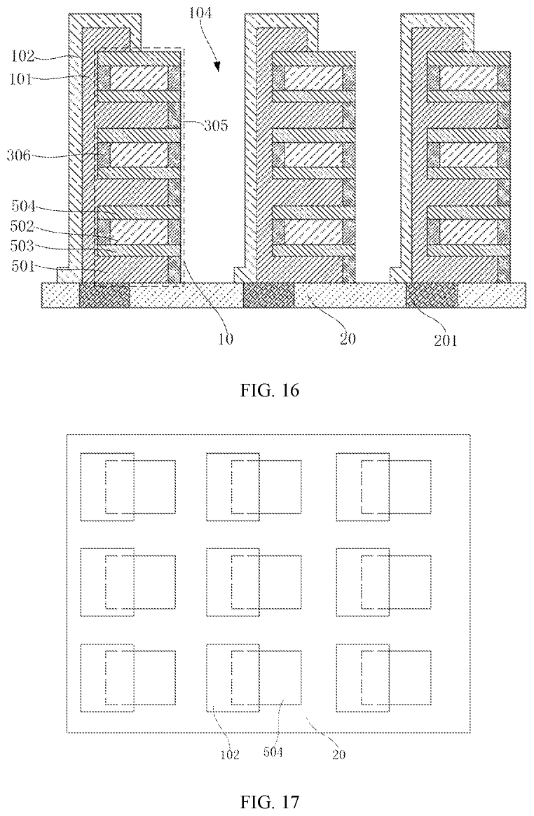

Continue to refer to FIG. 1, further, a conductive film 101 is wrapped on outside each of the plurality of storage structures 10, the conductive film 101 has a connection port, and the connection port 104 (refer to FIG. 16) extends in the direction perpendicular to the substrate 20, so as to expose all the bottom plates 301 and all the top plates 302 corresponding to the connection port 104. A first insulating block 305 is provided between the top plates 302 and the conductive film 101, so as to achieve insulation connection between each of all the top plates 302 and the conductive film 101. All the bottom plates 301 are bonded to the conductive film 101, so that all the bottom plates 301 of all the capacitor structures 30 in each of the plurality of storage structures 10 are electrically connected by the conductive film 101.

In an implementation in which each of the plurality of storage structures 10 is columnar, the conductive film 101 can be wrapped around the side walls of each of the plurality of storage structures 10 and a top wall of each of the plurality of storage structures away from the substrate 20, and the connection port is provided on the side walls and extends towards the substrate 20; the connection port can extend linearly towards the substrate 20, and certainly the connection port can also extend towards the substrate 20 in a curved manner, which is not limited in this embodiment.

A conductive filler 40 is filled between adjacent storage structures 10, and the conductive filler 40 is bonded to all the top plates 302 corresponding to the connection port, so that all the top plates 302 of all the capacitor structures 30 in each of the plurality of storage structures 10 are electrically connected by the conductive filler 40. In order to achieve insulation between the conductive film 101 and the conductive filler 40, an insulating film 102 can be covered on an outer side of the conductive film 101.

By the described arrangement, while achieving the connection between all the bottom plates 301 and the connection between all the top plates 302 in each of the plurality of storage structures 10, the conductive film 101 and the conductive filler 40 can also support the plurality of storage structures 10, so as to prevent the plurality of storage structures 10 from inclining.

In this embodiment, the conductive filler 40 is not only filled between the adjacent storage structures 10, the conductive filler 40 but also covers the top wall of each of the plurality of storage structures 10 away from the substrate 20, so that the top plates 302 in all of the plurality of storage structures 10 are electrically connected by the conductive filler 40. Such an arrangement simplifies a structure of the semiconductor structure, and facilitates processing and manufacturing of the semiconductor structure.

In the described implementations, a material of the conductive film 101 can include polysilicon etc., a material of the conductive filler 40 can include germanium silicon etc., and a material of the insulating film 102 can include silicon oxide etc.

Continue to refer to FIG. 1, the substrate 20 includes a plurality of contact pads 201, and each of the plurality of contact pads 201 is bonded to the bottom plate 301 close to the substrate 20 in one of the storage structure 10. With such an arrangement, by the plurality of contact pads 201, data stored in the plurality of storage structures 10 bonded to the contact pads can be read, or data is written into the plurality of storage structures 10 bonded to the contact pads. The structure of the semiconductor structure is further simplified.

Exemplarily, a plurality of holes can be formed on the substrate 20, and then one of the plurality of contact pads 201 are formed in one of the plurality of holes. Materials of the plurality of contact pads 201 can include conductive materials such as tungsten and copper.

Continue to refer to FIG. 1, in this embodiment, a connecting channel is enclosed by the first dielectric layer 303 and the second dielectric layer 304 which are adjacent to the top plate 302, and the top plate 302, the conductive filler 40 has connecting portions, one of the connecting portions extends into the connecting channel, and the connecting portion correspond to the connecting channel, so as to be bonded to the top plate 302 in the connecting channel. Correspondingly, in each of the plurality of storage structures 10, the connecting channel is provided corresponding to the top plate 302, the conductive filler 40 has connecting portions, and each of the connecting portions extends into the connecting channel, so as to be bonded to the corresponding top plate 302. The conductive filler 40 is bonded to the corresponding top plate 302 by the connecting portion, which can avoid poor contact between the conductive filler 40 and the top plate 302.

Further, a first insulating channel is further formed between the first dielectric layer 303 and the second dielectric layer 304 which are adjacent to the top plate 302, and the top plate 302, the first insulating channel is located between the conductive film 101 and the top plate 302, and the first insulating block 305 is located in the first insulating channel. With such an arrangement, the first insulating block 305 is accommodated in the first insulating channel, thereby preventing the first insulating block 305 from occupying spaces outside the plurality of storage structures 10.

In this embodiment, a second insulating channel is formed between the first dielectric layer 303 and the second dielectric layer 304 which are adjacent to the bottom plate 301, and the bottom plate 301, the second insulating channel is located between the bottom plate 301 and the conductive filler 40, and second insulating block 306 is located in the second insulating channel. With such an arrangement, the second insulating block 306 is accommodated in the second insulating channel, thereby preventing the second insulating block 306 from occupying spaces outside the plurality of storage structures 10.

It should be noted that the bottom plate 301 is bonded to the substrate 20, and correspondingly, the bottom plate 301 close to the substrate 20 in each of the plurality of storage structures 10, the substrate 20, and the first dielectric layer 303 also form a second insulating channel, and a second insulating block 306 is provided in the second insulating channel, so as to achieve insulation between the bottom plate 301 close to the substrate 20 and the conductive filler 40.

In the described implementations, there can be multiple materials for the first insulating block 305 and the second insulating block 306. For example, a material of the first insulating block 305 can include aluminum oxide, and a material for the second insulating block 306 can include silicon oxide, which are not limited in this embodiment.

Continue to refer to FIG. 1, further, the first insulating block 305 can be formed after an end of the top plate 302 facing the conductive film 101 is oxidized, and with such an arrangement, there is no need to separately manufacture the first insulating block 305, thereby simplifying manufacturing difficulty of the semiconductor structure. Likewise, the second insulating block 306 can be formed after an end of the bottom plate 301 facing the conductive filler 40 is oxidized, and with such an arrangement, there is no need to separately manufacture the second insulating block 306, thereby simplifying the manufacturing difficulty of the semiconductor structure. Exemplarily, in an implementation in which the bottom plate 301 is formed by polysilicon and the top plate 302 is formed by aluminum, the material of the first insulating block 305 is aluminum oxide and the material of the second insulating block 306 is silicon oxide.

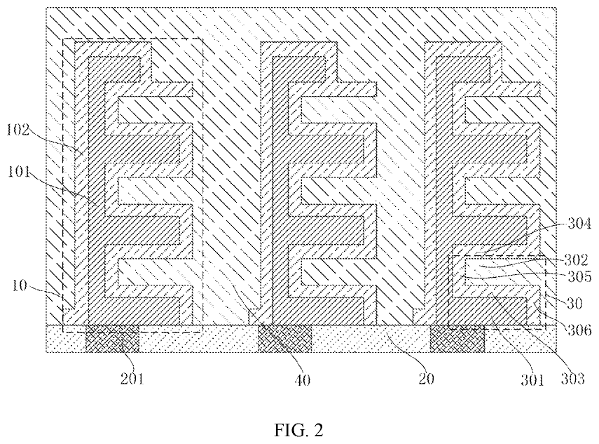

Please refer to FIG. 2, in other implementations, the first dielectric layer 303 and the second dielectric layer 304 are made of a same material, the first insulating block 305 and the second insulating block 306 are made of a same material as the first dielectric layer 303, and the insulating film 102 is also made of the same material as the first dielectric layer 303.

Further, the conductive film 101 and all the bottom plates 301 in a corresponding storage structure 10 are made of a same material, and the conductive film 101 and all the bottom plates 301 in the corresponding storage structure 10 are of an integrated structure; and the conductive filler 40 and all the top plates 302 in a corresponding storage structure 10 are made of a same material, and the conductive filler 40 and all the top plates 302 in the corresponding storage structure 10 are of an integrated structure.

By the described arrangement, the bottom plate 301, the second insulating block 306 and the conductive filler 40 on a side of the second insulating block 306 away from the bottom plate 301 constitute a capacitor; the top plate 302, the first insulating block 305 and the conductive film 101 directly facing the first insulating block 305 constitute a capacitor; and the conductive film 101, the insulating film 102 and the conductive filler 40 on a side of the insulating film 102 away from the conductive film 101 constitute a capacitor, such that the capacitance value of the plurality of capacitor structures 30 can be further increased, and the charge storage capability of the storage structures is further improved.

In the described implementations, the semiconductor structure can be a dynamic random access memory (simply referred to as DRAM), and definitely, the semiconductor structure can also be other structures, which is not limited in this embodiment.

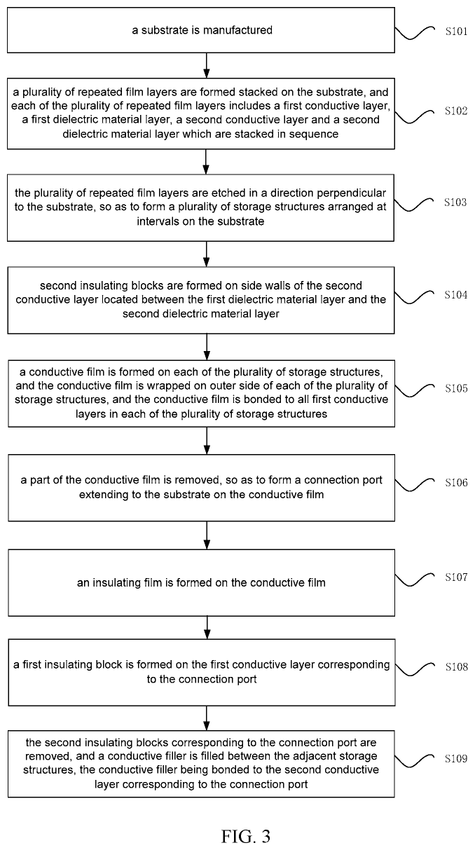

Please refer to FIG. 3, the embodiments of the present disclosure further provide a method for manufacturing a semiconductor structure, including:

S101: a substrate is manufactured.

The substrate can be of a plate shape. Exemplarily, a material of the substrate can include insulation materials such as silicon nitride and silicon oxide, and the material of the substrate is not limited in this embodiment.

Continue to refer to FIG. 3, after forming the substrate, the method further includes:

S102: a plurality of repeated film layers are formed stacked on the substrate, and each of the plurality of repeated film layers includes a first conductive layer, a first dielectric material layer, a second conductive layer and a second dielectric material layer which are stacked in sequence.

Please refer to FIG. 4, each of the plurality of repeated film layers 50, for example, includes four layer structures, and the first conductive layer 501 is provided close to the substrate 20, the first dielectric material layer 503 is provided between the first conductive layer 501 and the second conductive layer 502, and the second dielectric material layer 504 is located on a side of the second conductive layer 502 away from the substrate 20. In adjacent repeated film layers 50, the repeated film layer close to the substrate 20 is a first repeated film layer, the repeated film layer away from the substrate 20 is a second repeated film layer, the plurality of repeated film layers 50 are stacked on the substrate 20, so that the second dielectric material layer 504 in the first repeated film layer is attached to the first conductive layer 501 in the second repeated film layer.

The first conductive layer 501 and the second conductive layer 502 are made of conductive materials. Exemplarily, a material of the first conductive layer 501 can include polysilicon, and a material of the second conductive layer 502 can include aluminum, which is of course, not limited in this embodiment. The first conductive layer 501 and the second conductive layer 502 can also be made of other conductive materials.

Materials of the first dielectric material layer 503 and the second dielectric material layer 504 can be composed of materials with a relatively high dielectric constant (such as hafnium silicate oxide, hafnium oxide and zirconium oxide). Further, the first dielectric layer 503 and the second dielectric layer 504 can be made of a same material, and certainly the first dielectric layer 503 and the second dielectric layer 504 can also be made of different materials.

After forming the plurality of repeated film layers 50, the method for manufacturing the semiconductor structure further includes:

continue to refer to FIG. 3, S103: the plurality of repeated film layers are etched in a direction perpendicular to the substrate, so as to form a plurality of storage structures arranged at intervals on the substrate.

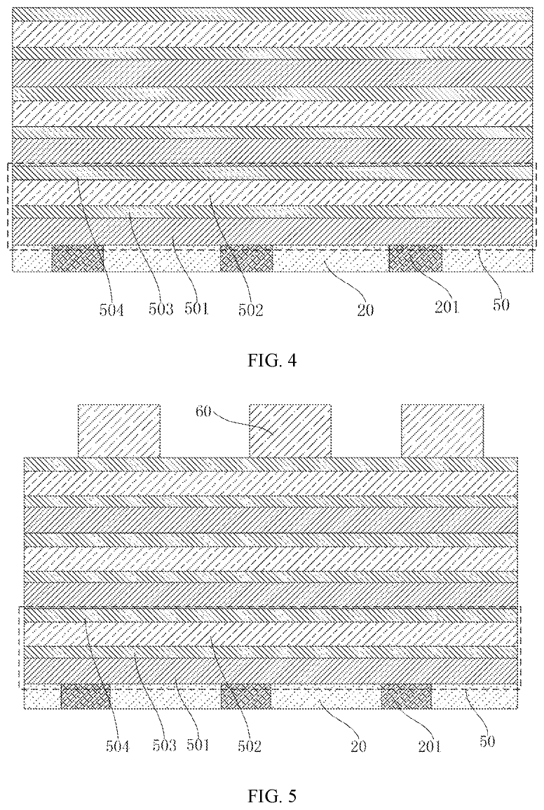

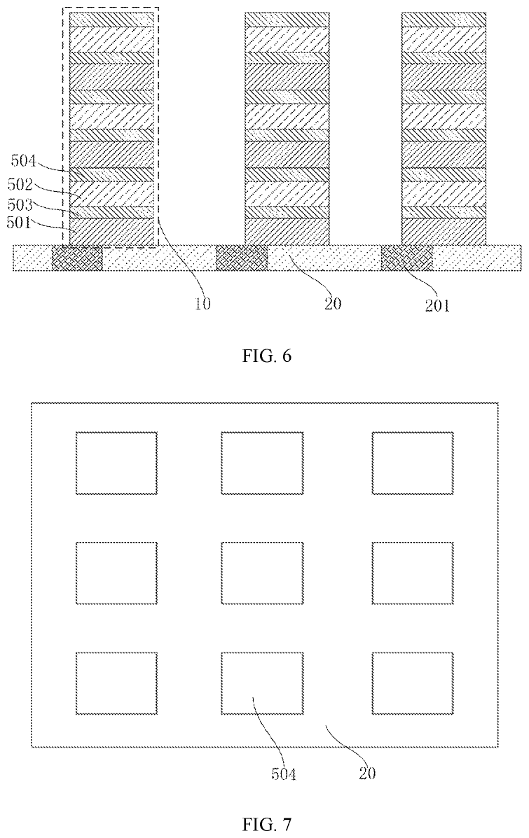

Please refer to FIGS. 5-7, exemplarily, the plurality of repeated film layers 50 are etched in the direction perpendicular to the substrate 20, to remove a part of the plurality of repeated film layers 50, so as to form a plurality of columnar storage structures 10; and each of the plurality of storage structures 10 can be cylindrical, and certainly each of the plurality of storage structures 10 can also be a quadrangular prism shape.

Specifically, an etching pattern layer 60 can be formed on a side of the plurality of repeated film layers 50 away from the substrate 20, and the etching pattern layer 60 includes a plurality of shielding blocks arranged at intervals; then the plurality of repeated film layers 50 are etched by the etching pattern layer 60 as a mask, parts of the plurality of repeated film layers 50 corresponding to the shielding blocks are retained, and rest parts of the plurality of repeated film layers 50 are removed, so as to form the plurality of columnar storage structures 10.

It should be noted that the plurality of repeated film layers 50 can be etched by wet etching or dry etching, and a etching process is not limited in this embodiment.

In the described implementation, any one of first dielectric material layer 503 in each of the plurality of storage structures can serve as a first dielectric layer, the first conductive layer 501 on a side of the first dielectric material layer 503 facing the substrate 20 serves as a bottom plate, and the second conductive layer 502 on a side of the first dielectric material layer 503 away from the substrate 20 serves as a top plate, and the bottom plate, the top plate, and the first dielectric layer form a capacitor. Likewise, any one of second dielectric material layers 504 can serve as a second dielectric layer, the second conductive layer 502 on a side of the second dielectric material layer 504 facing the substrate 20 serves as a top plate, and the first conductive layer 501 on a side of the second dielectric material layer 504 away from the substrate 20 serves as a bottom plate, and the bottom plate, the top plate and the first dielectric layer also form a capacitor, so as to increase the capacitance value of each of the plurality of storage structures 10.

Continue to refer to FIG. 3, after forming the plurality of storage structures 10, the method for manufacturing the semiconductor structure provided in this embodiment further includes:

S104: second insulating blocks are formed on side walls of the second conductive layer located between the first dielectric material layer and the second dielectric material layer.

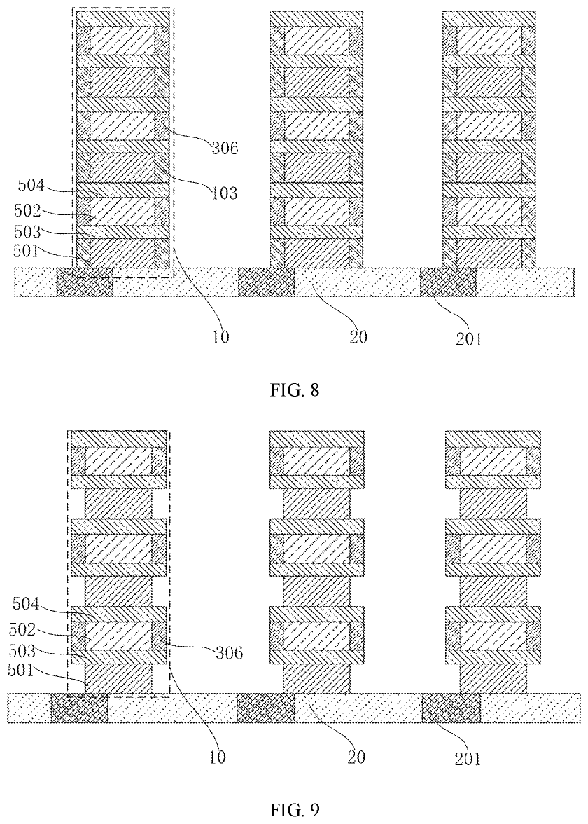

Please refer to FIGS. 8 and 9, in some implementations, the second insulating blocks 306 are formed specifically includes: an oxidation treatment is performed on the first conductive layer 501 and the second conductive layer 502, so as to form second insulating blocks 306 on the side walls which are perpendicular to the substrate 20, of the second conductive layer 502 located between the first dielectric material layer 503 and the second dielectric material layer 504, and at the same time intermediate insulating blocks 103 are formed on side walls, which are perpendicular to the substrate 20, of the first conductive layer 501 located between the first dielectric material layer 503 and the second dielectric material layer 504; and the intermediate insulating blocks 103 are removed after the intermediate insulating blocks 103 and the second insulating blocks 306 are formed.

The second insulating blocks 306 are formed by oxidation, thereby simplifying manufacturing difficulty of the plurality of storage structures 10.

In other implementations, a part of the top plate 302 can be removed by etching, so that the top plate 302 remained, and the first dielectric material layer 503 and the second dielectric material layer 504 which are located on two sides of the top plate 302 are enclosed to form a channel, and then an insulation material is filled in the channel, thereby forming the second insulating block 306.

Continue to refer to FIG. 3, after the second insulating blocks 306 are formed, the method further includes:

S105: a conductive film is formed on each of the plurality of storage structures, and the conductive film is wrapped on outer side of each of the plurality of storage structures, and the conductive film is bonded to all first conductive layers in each of the plurality of storage structures.

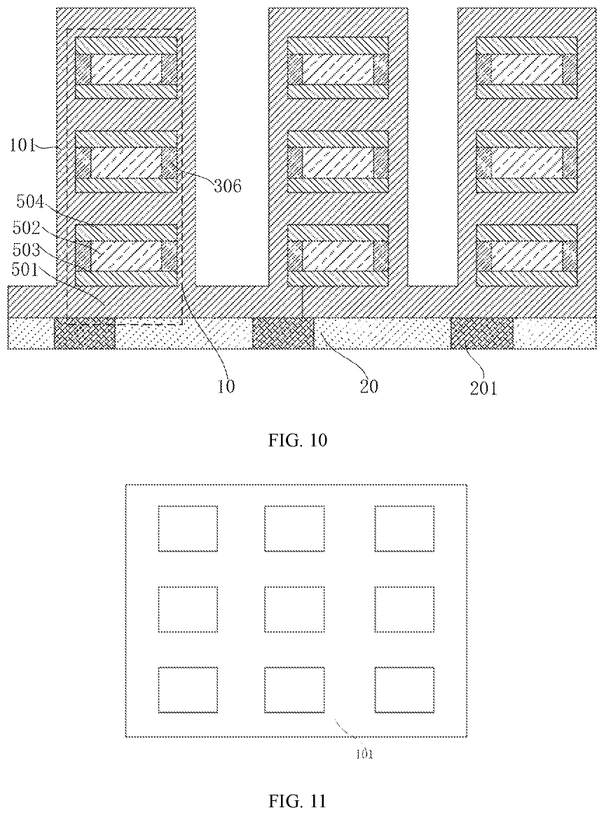

Please refer to FIGS. 10 and 11, the conductive film 101 is wrapped on the outer side of each of the plurality of storage structures 10, that is to say, the conductive film 101 is wrapped on all other side faces of each of the plurality of storage structures 10 except a side face bonded to the substrate 20. In an implementation in which each of the plurality of storage structures 10 is columnar, the conductive film 101 is wrapped around side walls, perpendicular to the substrate 20, of each of the plurality of storage structures 10 and a top wall of each of the plurality of storage structures away from the substrate 20.

In an implementation in which the second insulating blocks 306 are formed by oxidation, after the second insulating blocks 306 are formed, the intermediate insulating blocks 103 formed in the oxidation process are removed, so that a groove is formed between the bottom plate 301, the first dielectric material layer 503 and the second dielectric material layer 504 which are adjacent to the bottom plate 301; and in the process of forming the conductive film 101, a part of the conductive film 101 is filled in the groove, so as to achieve bonding between the conductive film 101 and the bottom plate 301.

Continue to refer to FIG. 3, after the conductive film 101 is formed, the method for manufacturing the semiconductor structure provided in this embodiment further includes:

S106: a part of the conductive film is removed, so as to form a connection port extending to the substrate on the conductive film.

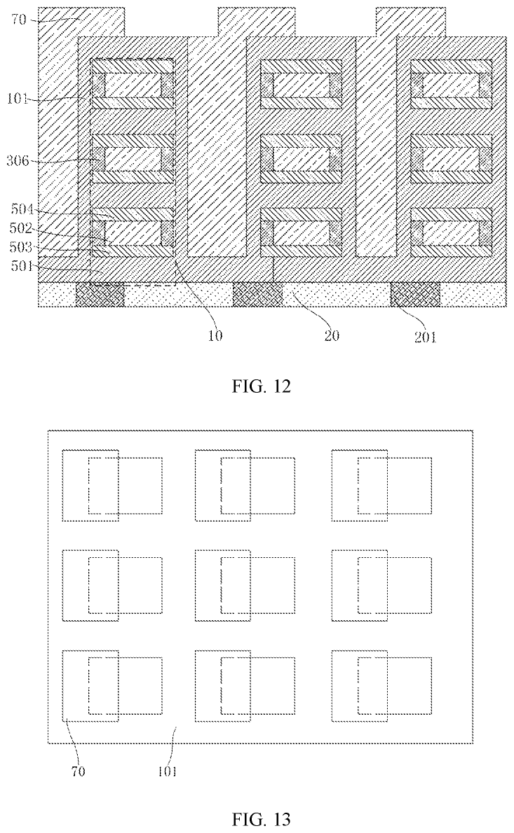

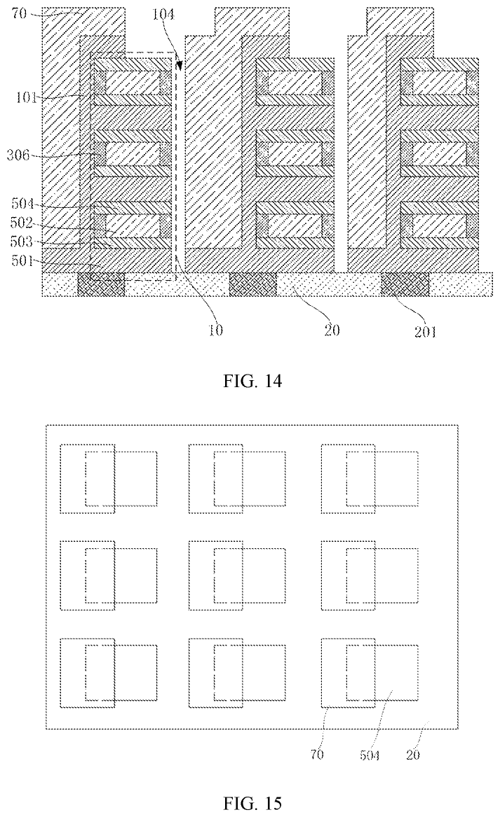

Please refer to FIGS. 12 to 15, specifically, specific steps for forming the connection port 104 can include: a mask layer 70 is formed on side walls of each of the plurality of storage structures 10 and an upper surface of each of the plurality of storage structures 10, the mask layer 70 including an etching pattern; and removing the part of the conductive film 101 by the mask layer 70 as a mask, to form the connection port 104. The connection port 104 is formed by etching, dimensional accuracy of the connection port 104 is improved.

In some embodiments, the etching pattern can include etching holes provided on the mask layer 70, each of the etching holes corresponds to one of the plurality of storage structures 10, and a projection of each of the etching holes on the substrate 20 only partially overlaps with a projection of the storage structure 10 correspondingly on the substrate 20, so that when the conductive film 101 is etched, the conductive film 101 covered by the mask layer 70 is retained, and the mask layer 70 corresponding to the etching holes is removed, and then connection ports 104 extending to the substrate 20 are formed on the mask layer 70. Further, when forming the mask layer 70, a part of the mask layer 70 is filled between adjacent storage structures 10, and the mask layer 70 located between the adjacent storage structures 10 and the mask layer 70 on one side of the etching holes together protect the conductive film 101, so as to prevent the conductive film 101 outside the connection port 104 from being damaged during etching.

After the connection port 104 is formed, the method for manufacturing the semiconductor structure provided in this embodiment further includes:

continue to refer to FIG. 3, S107, an insulating film is formed on the conductive film.

Please refer to FIGS. 16 and 17, the insulating film 102 covers all other side walls of the conductive film 101 other than a side wall bonded to each of the plurality of storage structures 10, so as to prevent an electrical connection between the conductive film 101 and other film layers.

Exemplarily, an oxidation treatment can be performed on a surface layer of the conductive film 101, so as to form the insulating film 102; that is to say, oxide films extending inward are formed on all the other side walls of the conductive film 101 other than the side wall bonded to each of the plurality of storage structures 10, and then the insulating film 102 is formed. With such an arrangement, the manufacturing difficulty of the insulating film 102 is simplified. Of course, in other implementations, the insulating film 102 can also be formed on the conductive film 101 by deposition, etc., and the method for forming the insulating film 102 is not limited in this embodiment.

Continue to refer to FIG. 3, after the insulating film 102 is formed, the method for manufacturing the semiconductor structure provided in this embodiment further includes:

S108: a first insulating block is formed on the first conductive layer corresponding to the connection port.

Continue to refer to FIGS. 16 and 17, specifically, the first insulating block 305 is formed can include: an oxidation treatment is performed on the first conductive layer 501 directly facing the connection port 104, so as to form the first insulating blocks 305. With such an arrangement, the manufacturing difficulty of the first insulating block 305 is simplified. Certainly, in other implementations, a part of the first conductive layer 501 corresponding to the connection port 104 can also be removed first so as to form notch, and then the notch are filled with an insulation material, so as to form the first insulating block 305.

In an implementation in which the insulating film 102 is formed by oxidizing the surface layer of the conductive film 101, the conductive film 101 can be oxidized while performing the oxidation treatment on the first conductive layer 501, so that the insulating film 102 and the first insulating block 305 are formed at the same time, thereby simplifying the manufacturing difficulty of the semiconductor structure.

Continue to refer to FIG. 3, after the first insulating block 305 is formed, the method for manufacturing the semiconductor structure provided in this embodiment further includes:

S109: the second insulating blocks corresponding to the connection port are removed, and a conductive filler is filled between the adjacent storage structures, the conductive filler being bonded to the second conductive layer corresponding to the connection port.

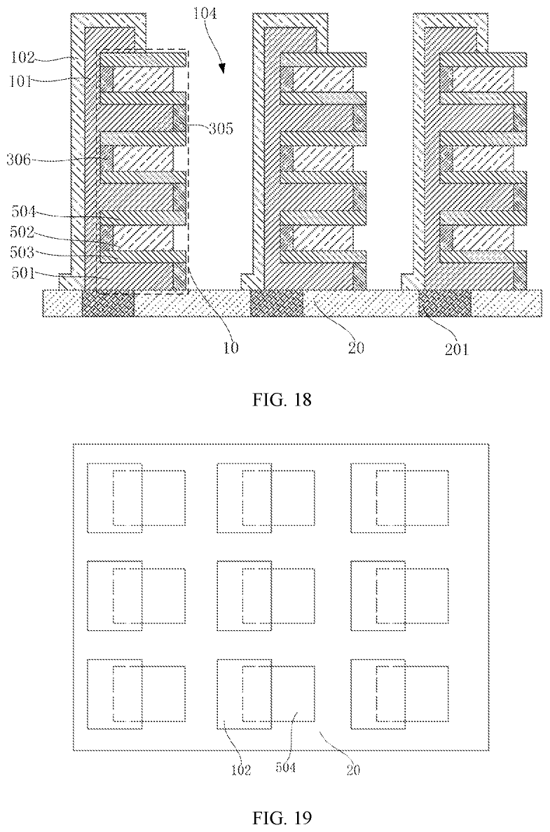

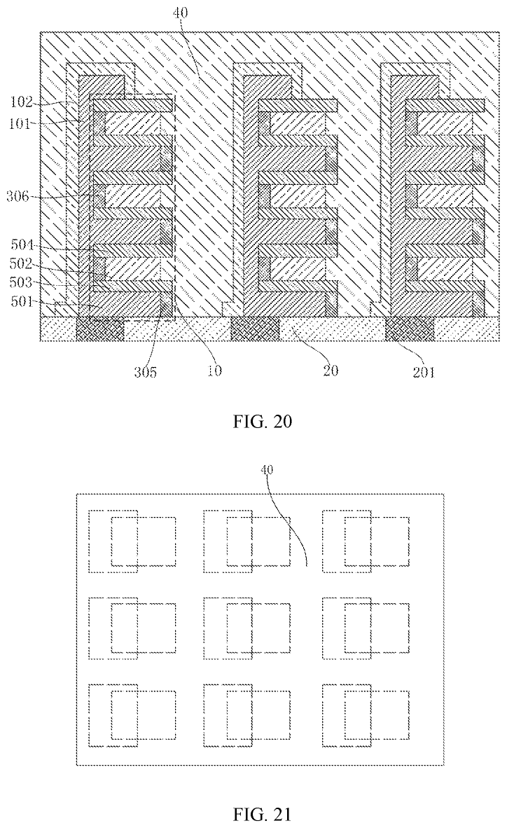

Continue to refer to FIGS. 18-21, specifically, after the second insulating blocks 306 corresponding to the connection port 104 are removed, a connecting channel is formed by the second conductive layer 502, and the first dielectric material layer 503 and the second dielectric material layer 504 which are located at two sides of the second conductive layer 502; and when the conductive filler 40 is formed, a part of the conductive filler 40 is filled in the connecting channel, so as to form a connecting portion bonded to the second conductive layer 502.

Further, the conductive filler 40 is not only filled between the adjacent storage structures 10, the conductive filler 40 but also covers the top wall of each of the plurality of storage structures 10 away from the substrate 20, so that all second conductive layers 502 in each of the plurality of storage structures 10 are electrically connected by the conductive filler 40. Such an arrangement simplifies the structure of the semiconductor structure, and facilitates processing and manufacturing of the semiconductor structure.

In the described implementations, specific steps for manufacturing the substrate 20 include:

an insulating base layer is formed; and then a plurality of holes are formed on the insulating base layer, and a contact pad 201 is formed in each of the plurality of holes; and the contact pad 201 is configured to be bonded to the first conductive layer 501 close to the substrate 20 in each of the plurality of storage structures 10. With such arrangement, by the contact pad 201, data stored in each of the plurality of storage structures 10 corresponding to the contact pad 201 can be read, or data is written into each of the plurality of storage structures 10.

Exemplarily, materials of the insulating base layer can include insulation materials such as silicon nitride and silicon oxide, which is not limited in this embodiment.

In the method for manufacturing the semiconductor structure provided in this embodiment, in the manufactured semiconductor structure, the plurality of storage structures 10 are arranged at intervals on the substrate 20, each of the plurality of storage structures 10 includes the plurality of capacitor structures stacked in the direction perpendicular to the substrate 20; each of the plurality of capacitor structures includes the first conductive layer 501 and the second conductive layer 502 arranged opposite to each other, and the first dielectric material layer 503 located between the first conductive layer 501 and the second conductive layer 502, and the first conductive layer 501 and the second conductive layer 502 are both parallel to the substrate 20, all the first conductive layers 501 in each of the plurality of storage structures 10 are electrically connected, and all the second conductive layers 502 in each of the plurality of storage structures 10 are electrically connected. Both the first conductive layer 501 and the second conductive layer 502 are parallel to the substrate 20, and the first conductive layer 501 and the second conductive layer 502 extend in a plane parallel to the substrate 20, a decrease in a height of the semiconductor structure does not affect areas of the first conductive layer 501 and the second conductive layer 502, and thus, compared with a tubular capacitor structure, a capacitance value of the plurality of capacitor structures is increased, further improving charge storage capability of the semiconductor structure.

Finally, it should be noted that the embodiments above are only used to explain the technical solutions of some embodiments of the present disclosure, rather than limit same. Although some embodiments of the present disclosure have been explained in detail with reference to the embodiments above, a person of ordinary skill in the art would have understood that they still could modify the technical solutions disclosed in the described embodiments or make equivalent replacements to some or all of the technical features therein. However, these modifications or replacements shall not render that the nature of the corresponding technical solutions departs from the scope of the technical solutions in the embodiments of the present disclosure.

What is claimed is:

1. A semiconductor structure, comprising:
a substrate; and
a plurality of storage structures provided on the substrate and distributed at intervals;
wherein each of the plurality of storage structures comprises a plurality of capacitor structures stacked in a direction perpendicular to the substrate, each of the plurality of capacitor structures comprises a bottom plate and a top plate arranged opposite to each other, and a first dielectric layer is located between the bottom plate and the top plate, and the bottom plate and the top plate are both parallel to the substrate; and
all bottom plates in each of the plurality of storage structures are electrically connected to one another, and all top plates in each of the plurality of storage structures are electrically connected to one another.

2. The semiconductor structure according to claim 1, wherein
the bottom plate of each of the plurality of capacitor structures is arranged close to the substrate; and
a second dielectric layer is provided between adjacent capacitor structures.

3. The semiconductor structure according to claim 2, wherein the first dielectric layer and the second dielectric layer are made of a same material.

4. The semiconductor structure according to claim 2, wherein
a conductive film is wrapped on outside each of the plurality of storage structures, the conductive film has a connection port, and the connection port extends in the direction perpendicular to the substrate, so as to expose all the bottom plates and all the top plates corresponding to the connection port;
a first insulating block is provided between each of all the top plates and the conductive film;
an insulating film covers an outer side of the conductive film;
a conductive filler is filled between adjacent storage structures, and the conductive filler is bonded to all the top plates corresponding to the connection port; and
a second insulating block is provided between the conductive filler and each of all the bottom plates.

5. The semiconductor structure according to claim 4, wherein a connecting channel is enclosed by the first dielectric layer and the second dielectric layer which are adjacent to the top plate, and the top plate, the conductive filler has connecting portions, and one of the connecting portions extends into the connecting channel so as to be bonded to the top plate.

6. The semiconductor structure according to claim 4, wherein a first insulating channel is formed between the first dielectric layer and the second dielectric layer which are adjacent to the top plate, and the top plate, the first insulating channel is located between the conductive film and the top plate, and the first insulating block is located in the first insulating channel.

7. The semiconductor structure according to claim 6, wherein the first insulating block is formed by oxidizing an end of the top plate facing the conductive film.

8. The semiconductor structure according to claim 4, wherein a second insulating channel is formed between the first dielectric layer and the second dielectric layer adjacent to the bottom plate, and the bottom plate, the second insulating channel is located between the bottom plate and the conductive filler, and the second insulating block is located in the second insulating channel.

9. The semiconductor structure according to claim 8, wherein the second insulating block is formed by oxidizing an end of the bottom plate facing the conductive filler.

10. The semiconductor structure according to claim 4, wherein the insulating film is formed by oxidizing a surface layer of the conductive film.

11. The semiconductor structure according to claim 4, wherein the substrate comprises a plurality of contact pads, wherein each of the plurality of contact pads is bonded to the bottom plate close to the substrate in one of the storage structure.

12. A method for manufacturing a semiconductor structure, comprising:
manufacturing a substrate;
forming a plurality of repeated film layers stacked on the substrate, wherein each of the plurality of repeated film layers comprises a first conductive layer, a first dielectric material layer, a second conductive layer and a second dielectric material layer which are stacked in sequence;
etching the plurality of repeated film layers in a direction perpendicular to the substrate, so as to form a plurality of storage structures arranged at intervals on the substrate;
forming second insulating blocks on side walls of the second conductive layer located between the first dielectric material layer and the second dielectric material layer;
forming a conductive film on each of the plurality of storage structures, wherein the conductive film is wrapped on outer side of each of the plurality of storage structures, and the conductive film is bonded to all first conductive layers in each of the plurality of storage structures;
removing a part of the conductive film, to form a connection port extending to the substrate on the conductive film;
forming an insulating film on the conductive film;
forming a first insulating block on the first conductive layer corresponding to the connection port; and
removing the second insulating blocks corresponding to the connection port, and filling a conductive filler between adjacent storage structures, the conductive filler being bonded to the second conductive layer corresponding to the connection port.

13. The method for manufacturing the semiconductor structure according to claim 12, wherein forming the second insulating blocks on the side walls of the second conductive layer located between the first dielectric material layer and the second dielectric material layer comprises:
performing an oxidation treatment on the first conductive layer and the second conductive layer, so as to form the second insulating blocks on the side walls of the second conductive layer located between the first dielectric material layer and the second dielectric material layer; at the same time, so as to form intermediate insulating blocks on side walls of the first conductive layer located between the first dielectric material layer and the second dielectric material layer; and
removing the intermediate insulating blocks after forming the intermediate insulating blocks and the second insulating blocks.

14. The method for manufacturing the semiconductor structure according to claim 12, wherein removing the part of the conductive film, to form the connection port extending to the substrate on the conductive film comprises:
forming a mask layer on side walls of each of the plurality of storage structures and an upper surface of each of the plurality of storage structures, wherein the mask layer comprises an etching pattern; and
removing the part of the conductive film by the mask layer as a mask, to form the connection port.

15. The method for manufacturing the semiconductor structure according to claim 12, wherein forming the insulating film and the first insulating block comprises:
performing an oxidization treatment on a surface layer of the conductive film and a part of the first conductive layer directly facing the connection port, so as to form the insulating film and the first insulating block.

16. The method for manufacturing the semiconductor structure according to claim 12, wherein manufacturing the substrate comprises:
forming an insulating base layer; and
forming a plurality of holes on the insulating base layer, and forming a contact pad in each of the plurality of holes;
wherein the contact pad is configured to be bonded to the first conductive layer close to the substrate in each of the plurality of storage structures.
